(19) United States
(12) Patent Application Publication
(10) Pub. No.: US 2017/0149208 A1
(43) Pub. Date: May 25, 2017

(54) A LASER CONTROL CIRCUIT, CONTROL METHOD AND LASER INK LINE DEVICE WITH LASER CONTROL CIRCUIT

(71) Applicant: CHANGZHOU HUADA KEJIE OPTO-ELECTRO INSTRUMENT CO., LTD., Jiangsu (CN)

(72) Inventors: Ou ZHANG, Jiangsu (CN); Qing NIU, Jiangsu (CN); Junjie FU, Jiangsu (CN)

(73) Assignee: CHANGZHOU HUADA KEJIE OPTO-ELECTRO INSTRUMENT CO., LTD., Jiangsu (CN)

(21) Appl. No.: 15/127,541

(22) PCT Filed: Feb. 13, 2015
(86) PCT No.: PCT/CN2015/072970

§ 371 Date: Sep. 20, 2016

(30) Foreign Application Priority Data
Mar. 20, 2014 (CN) 201410106424.6

(51) Int. Cl. H01S 5/042

(52) U.S. Cl. CPC H01S 5/0428

(57) ABSTRACT

A laser control circuit, comprising at least two laser tubes and a control unit controlling the at least two laser tubes respectively; the control unit sends control signals to the at least two laser tubes to control startup/shutdown thereof. The control unit comprises: a main pulse signal generator and a logic control unit; the main pulse signal generator, the logic control unit and the at least two laser tubes are connected successively; and the logic control unit classifies the control signals into different types of control signals and sends to the at least two laser tubes, causing the at least two laser tubes to present different working conditions. The laser control circuit has more flexible control over the laser tubes, reduces working current of the laser tubes and allows the working current to be steadier, thus avoiding peak interference.

### TECHNICAL FIELD

The present invention relates to a laser device, and specifically to a laser control circuit, a control method and a laser ink line device with laser control circuit.

### BACKGROUND ART

The laser ink line device is a regular device in the field of laser devices. As for the control manner for the laser tubes in a laser ink line device, as shown in FIG. 1, it is regularly applied to provide with a very simple control circuit in which a control signal generator is configured for each laser tube and directly sends square waves or high-low level to control the on-off of laser tubes.

As the control circuit sends the same control signals to all laser tubes in the above manner, the open/close state of all laser tubes are same and the function is single which can not satisfy with the users needs. Moreover, even more important, the open/close of laser tubes in the same time will cause the peak interference, that is, when the current is larger, the frequency of the peak interference will improve, causing damage for the laser tubes. In additional, as Alkaline dry battery and NI-MH battery provide with the power source for the laser ink line device, a non-continuous large current will discharge, which will shorten the discharge time of batteries.

In order to overcome the aforementioned limitation, solve the problem in the prior art and improve the user experience for the laser ink line device, the present invention provides a new laser control circuit for controlling laser tubes more flexibly, reducing the working current for laser tubes and avoiding the peak interference.

### SUMMARY OF THE INVENTION

The objective of the present invention is to provide a laser control circuit so as to provide continuously and smoothly working current to the laser ink line device with the laser control circuit and reduce the damages caused by the peak interference.

The present invention provides a laser control circuit, comprising at least two laser tubes and a control unit controlling the at least two laser tubes respectively; the control unit sends control signals to the at least two laser tubes to control startup/shutdown thereof; the control unit comprises: a main pulse signal generator and a logic control unit; the main pulse signal generator, the logic control unit and the at least two laser tubes are connected successively; the main pulse signal generator sends control signals to the logic control unit; and the logic control unit classifies the control signals into different types of control signals and sends to the at least two laser tubes, causing the at least two laser tubes to present different working conditions.

Preferably, the logic control unit comprises a NOT gate; the at least two laser tubes includes a first laser tube group and a second laser tube group; an output end of the main pulse signal generator is connected with an input end of the NOT gate and the first laser tube group so as to send a main control signal to the input end of the NOT gate and the first laser tube group; an output end of the NOT gate connected with the second laser tube group is configured for having the main control signal be inverted and having the first and second laser group startup/shutdown alternately.

Preferably, the control unit further comprises: at least two secondary pulse signal generators and at least two AND gates; each secondary pulse signal generator is connected with a first input end of each AND gate and sends a secondary pulse signal to the AND gate; a second input end of the AND gate is connected with the main pulse signal generator, while an output end of the AND gate is connected with each laser tube of the first laser tube group; the second input end of the AND gate is connected with the output end of NOT gate so that the main pulse signal generator and the secondary pulse signal generator control the startup/shutdown of each laser tube, while an output end of the AND gate is connected with each laser tube of the second laser tube group.

Preferably, the main pulse signal generator and the secondary pulse signal generator is a Single Chip Microcomputer.

Preferably, the main control signal and the secondary control signal have a frequency of 10 kHz.

Preferably, the first and second laser tube group includes one laser tube respectively.

The present invention further provides a laser ink line device with the laser control circuit

The present invention further provides a control method for laser tubes, comprising: classifying the laser tubes into a first laser tube group and a second laser tube group; providing with a control unit corresponding to the first and second laser tube group so as to send control signals to the first and second laser tube group respectively; and having the control unit control the first and second laser group to startup/shutdown alternately.

Preferably, the control unit comprises an AND gate configured for having the first control signal and second control signal be inverted.

In the above technical solution, the startup/shutdown state of the first and second laser tube group may be alternately, and the working current is controlled above the maximum working current of the laser tube group instead of the superposition in the prior art, so as to reduce the working current, avoid the peak interference and prevent the laser tubes from being damaged. Additionally, a continuously and smoothly current is provided when the laser ink line device works, which may extend discharge time of Alkaline dry battery and NI-MH battery.

### BRIEF DESCRIPTION OF THE DRAWINGS

FIG. 1 shows the control circuit in the prior art; and

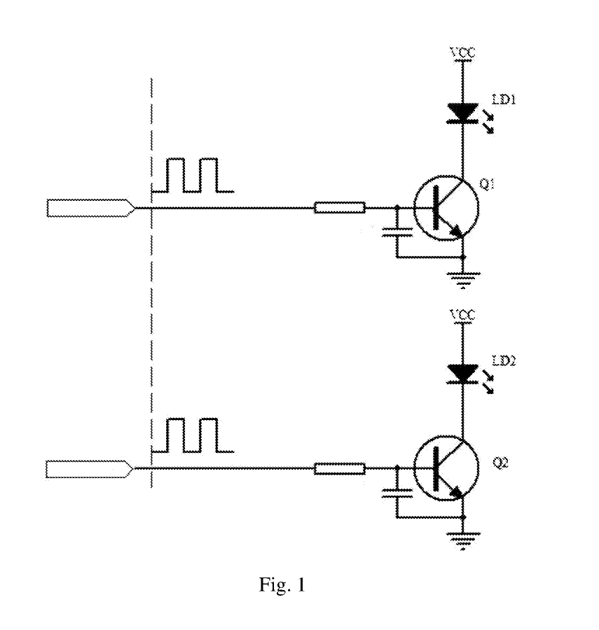

FIG. 2 shows the control circuit in a preferred embodiment of the present invention.

1 main pulse signal generator;

2 secondary pulse signal generator.

### DETAILED DESCRIPTION OF THE EMBODIMENTS

The advantages of the present invention will be detailed and described in reference to the drawings and the embodiments as follows.

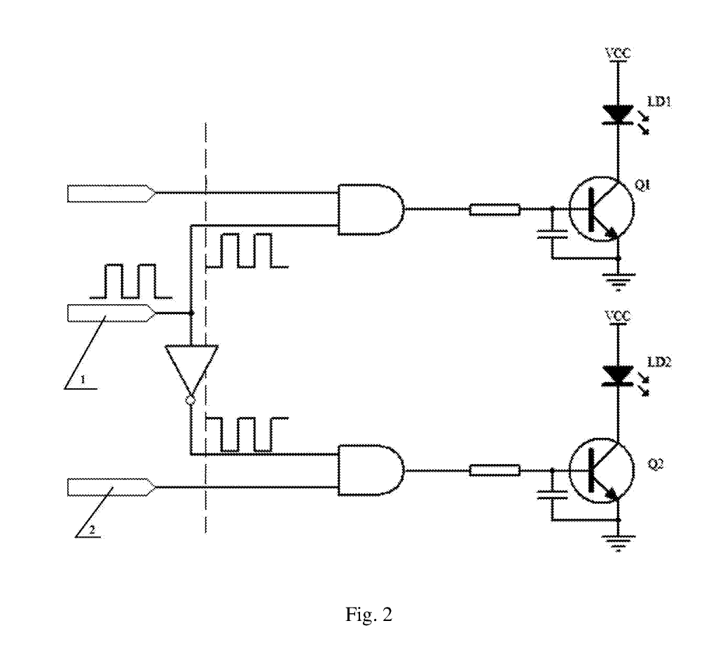

As shown in FIG. 2, in a preferred embodiment of the present invention, a laser control circuit comprises at least two laser tubes and a control unit configured for controlling the at least two laser tubes, so that the control unit may control the startup/shutdown state of the laser tubes through sending control signals to each laser tube. In the present invention, in order to solve the above-mentioned problem, the at least two laser tubes are classified into two group, i.e., a first laser tube and a second laser tube. It is pointed out that the method of classification is not limited, and the user, depending on the actual working requirements, may classify the laser to be a first group and a second group on basis of different displaying status as needed, for example, may define one laser tube as a first laser group and define another one as a second laser group, or classify all laser tubes into the corresponding two. The classification is flexible.

Furthermore, the control unit further comprises a main pulse signal generator 11, as same as other controllers contained in the control unit, the main pulse signal generator 11 is configured for sending a control signal to control the status of laser tubes. Moreover, the control unit further comprises a logical control unit provided among the main pulse signal generator 11, the first and second laser groups to classify the control signals from the main pulse signals into two for being sent to the first and second laser groups separately. After receiving the different control signals, the first laser group will present a startup/shutdown state while the second laser group presents a shutdown/startup state which is contrary to that of the first laser group.

In a preferred embodiment, the logic control unit is a NOT gate which is connected with the main pulse signal generator 1, the first and second laser group in a manner of: an output end of the main pulse signal generator 1 is connected with an input end of the NOT gate and the first laser tube, so that the first laser may directly receives the control signals from the main pulse signal generator 1 and determine if startup or shutdown according to the control signals as received; an output end of the NOT gate is connected with the second laser tube group, so that control signals from the main pulse signal generator 1 may be sent to the second laser tube group through the NOT gate, in this circumstances, the control signals received from the second laser group are always inverted to that received from the first laser group, i.e., the working state of the first and second laser group is always contrary to each other.

In other embodiments, the logic control unit may be a NAND gate (not shown), i.e., both two output ends of the main pulse signal generator 1 are connected with an input end of the NAND gate. In additional, one of the output ends of the main pulse signal generator 1 is directly connected with the first laser group so that the control signals received by the first laser group are the control signals sent from the main pulse signal generator 1. If the output of the control signal through the NAND gate is a low level while its input is a high level, the first laser group will start and the second laser group will close; if the output is a high level while the input is a low level, the second laser group will startup and the first laser group will shutdown, which causes the two laser groups being inverted.

Compared with above-mentioned logical control unit which is a NOT gate, the control circuit for a NAND gate is more complicated and requires much more for the circuit, therefore, a NOT gate would be more simply and practical.

It is understood that the person skilled in the art may obtain the logical control unit defined in the present application through the combination of different logical modules, the above-mentioned embodiment is not a limit to the logical control unit, and any logical control unit having the corresponding effective may be applied in the present application.

In order to have each laser tube controlled by the external control device, more preferably, the control unit further comprises at least two secondary pulse signal generators 2 and at least two AND gates. The secondary pulse signal generators are corresponding to the main pulse signal generators, specially, one secondary pulse signal generator and one AND gate are corresponding to each laser tube with the following connecting method: each secondary pulse signal generator 2 is connected with a first input end of the AND gate for sending control signals to the AND gate; the connection for a second output of the NOT gate depends on the classification of laser tubes, specially, one second input end of the AND gate connected with the first laser tube group is further connected with the main pulse signal generator 1, while the other second input end of the AND gate connected with the second laser tube group is connected with the output end of the NOT gate, i.e., the inputs of both two input ends of the AND gate connected with the first laser tube group are secondary controls signals and main control signals respectively, instead, the inputs of both two input ends of the AND gate connected with the second laser tube group are secondary control signals and inverted main control signals respectively. In the meantime, output ends of the AND gate are connected with each laser tube.

In this circumstance, the laser tubes can determine if startup/shutdown on the basis of if the main control signals are inverted or not only when the input of the secondary pulse signal is a high level. When the external control device is under control and the input of the secondary pulse signal is a low level, the output of the AND gate must be a low level and the laser tubes will not be startup, whenever the input of the second end of the AND gate is a high or low level. Therefore, users may control the startup/shutdown of laser tubers by handing an external control device.

In a preferred embodiment, the main and secondary pulse signal generator 1, 2 is a Single Chip Microcomputer (“SCM”) which having the function of adjusting control signals. Compared with a simple timer and other time counters, it may improve the duty ratio of control signals.

The main control signal and the secondary control signal may be a control signal with frequency of 10 kHz. Users may select different frequency, e.g., 7.8125 kHz, 5 kHz etc. The 10 kHz may improve the anti-interference performance against sunshine when a high laser detects, although the selection of the frequency is determined by the needs of a laser detector.

In all above-mentioned preferred embodiments, quantity of laser tubers included by first and second laser tube group may be one. As more laser tubers will require more working current superposition, which cause the peak pulse interference when open or close the power source, quantity of laser tubers shall be two, one for the first laser group and the other one for the second laser group, so that the working current will be the maximum current of the two laser tubes. Specially, as the following table shows, the first laser tube contained in the first laser group is defined as I₁ and the first laser tube contained in the first laser group is defined as I₂.

| | | |
|---|---|---|
| Secondary control signal | 1 | 0 |
| Working current of the prior art | I₁ + I₂ | 0 |

| | | | | |
|---|---|---|---|---|
| Main Control Signal | 1 | 0 | 1 | 0 |
| Working current of the present | I₁ | I₂ | 0 | 0 |
| invention | | | | |

In the prior art, the maximum current of a laser ink line device is the sum of two laser tubes, i.e., I₁+I₂. In the present application, since the two laser tubes open alternatively, the maximum current will be I₁ when the first laser tube works, and the maximum current will be I₂ when the second laser tube works. Compared with the prior art, the maximum current will reduce 50% than that of the prior art if the working current of the first laser tube I₁ is equal to that of the second laser tube I₂, the working current will be more smoothly and continuously, reducing the damages caused by the peak interference.

The present application further discloses a laser ink line device with the laser control circuit as above-mentioned, since the method for connecting the control circuit and an external circuit does not change, the control circuit may be provided in the laser ink line device by the connecting method which is same as that in the prior art, so that the working current would be more smoothly and continuously, and the laser effects would be more variously.

The present application further discloses a control method of the above laser tube. Firstly, classifying all laser tubes into a first laser tube group and a second laser tube group so as to satisfy with the requirements of presenting various effects; Secondly, providing with a control unit corresponding to the first and second laser tube group so as to send a first and second control signal to the first and second laser tube group respectively. According to the different control signals, the control unit completes the alternately startup/shutdown of the first and second laser group.

Wherein, as applied in the above preferred embodiments, the control unit includes a logical control unit, preferred is a AND gate, classifying the control signals into original control signals and inverted control signals, the first control signals are the main control signals and the second control signals are the inverted main control signals.

In the above technical solution, the startup/shutdown state of the first and second laser tube group may be alternately, and the working current is controlled above the maximum working current of the laser tube group instead of the superposition in the prior art, so as to reduce the working current, avoid the interference from peak and prevent the laser tubes from being damaged. Additionally, a continuously and smoothly current is provided when the laser ink line device works, which may extend discharge time of Alkaline dry battery and NI-MH battery.

It should be noted that the embodiments of the present invention has a preferred implementation, and will not limit the present invention in any form, and any technician skilled in the field may change or modify to equivalent effective embodiments by using the above-described technique. Whenever the contents do not depart from the technical proposal in the present invention, any revision or equivalent change and modification of the above embodiments according to the technical substance of the present invention are all in the scope of the technical proposal in the present invention.

1. A laser control circuit, comprising at least two laser tubes and a control unit controlling the at least two laser tubes respectively; the control unit sends control signals to the at least two laser tubes to control startup/shutdown thereof; characterized in that, the control unit comprises:
a main pulse signal generator and a logic control unit;
the main pulse signal generator, the logic control unit and the at least two laser tubes are connected successively;
the main pulse signal generator sends control signals to the logic control unit; and
the logic control unit classifies the control signals into different types of control signals and sends to the at least two laser tubes, causing the at least two laser tubes to present different working conditions.

2. The laser control circuit according to claim 1, wherein
the logic control unit comprises a NOT gate;
the at least two laser tubes includes a first laser tube group and a second laser tube group;
an output end of the main pulse signal generator is connected with an input end of the NOT gate and the first laser tube group so as to send a main control signal to the input end of the NOT gate and the first laser tube group; and
an output end of the NOT gate connected with the second laser tube group is configured for having the main control signal be inverted and having the first and second laser group startup/shutdown alternately.

3. The laser control circuit according to claim 2, wherein the control unit further comprises:
at least two secondary pulse signal generators and at least two AND gates;
each secondary pulse signal generator is connected with a first input end of each AND gate and send a secondary pulse signal to the AND gate;
a second input end of the AND gate is connected with the main pulse signal generator, while an output end of the AND gate is connected with each laser tube of the first laser tube group; and
the second input end of the AND gate is connected with the output end of NOT gate so that the main pulse signal generator and the secondary pulse signal generator control the startup/shutdown of each laser tube, while an output end of the AND gate is connected with each laser tube of the second laser tube group.

4. The laser control circuit according to claim 3, wherein the main pulse signal generator and the secondary pulse signal generator is a Single Chip Microcomputer.

5. The laser control circuit according to claim 3, wherein the main control signal and the secondary control signal have a frequency of 10kHz.

6. The laser control circuit according to claim 1, wherein the first and second laser tube group includes one laser tube respectively.

7. A laser ink line device with the laser control circuit of claim 1.

8. A control method for laser tubes, comprising:
classifying the laser tubes into a first laser tube group and a second laser tube group;
providing with a control unit corresponding to the first and second laser tube group so as to send control signals to the first and second laser tube group respectively; and
having the control unit control the first and second laser group to startup/shutdown alternately.

9. The control method according to claim 8, wherein the control unit comprises an AND gate configured for having the first control signal and second control signal be inverted.
